(19) United States
(12) Patent Application Publication
(10) Pub. No.: US 2005/0178333 A1
(43) Pub. Date: Aug. 18, 2005

(54) System and method of CVD chamber cleaning

(75) Inventors: Chou San Nelson Loke, Tokyo (JP); Kenichi Kagami, Tokyo (JP); Kiyoshi Satoh, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 10/781,247

(22) Filed: Feb. 18, 2004

(51) Int. Cl. B05D 3/14; C23C 16/00

(52) U.S. Cl. 118/723 ME; 427/569

(57) ABSTRACT

A thin-film deposition system includes a plasma CVD reactor; a remote plasma chamber; and an electromagnetic wave generator for emitting electromagnetic waves to an interior of the reactor. Unwanted reaction products adhering to an inner surface of the reactor absorb electromagnetic waves are effectively removed.

### BACKGROUND OF THE INVENTION

1. Field of the Invention

This invention relates generally to a method for cleaning a plasma CVD (chemical vapor deposition) reactor and a plasma CVD apparatus provided with a cleaning device.

2. Description of the Related Art

In a single-substrate- or small-batch substrate-processing system, during CVD processing, a film is formed not only on a substrate but also on inner walls or other inner parts of a CVD chamber. An unwanted film formed on the inner parts of the chamber produces particles which fall on a substrate during CVD processing and degrade the quality of a film on the substrate. Thus, the CVD chamber is cleaned periodically by using an in-situ cleaning process to remove unwanted adhesive products from an inner surface of the CVD chamber.

In conventional LSI (large scale integration) devices such as CPU, memory, and system LSI, an insulator formed between metal lines is typically silicon dioxide (SiH4-based SiO2 films or TEOS-based SiO2 films) or fluorine-containing silicon oxide. As a demand for micro devices increases, a reduction of the resistance of metal lines and a reduction of the capacitance of insulators between metal lines become more required. Cu is applied as a conductor instead of an aluminum alloy to reduce the resistance of metal lines, and a low-k film is used as an insulator instead of SiO2 and related materials. In this new technology, SiC is used to replace SiN in combination with low-k material as a barrier etch stop layer. The dielectric constant of this film is around 3.8 to 4.4.

As the device dimensions continuously shrink, the RC time delay of an interconnect system becomes one of the most critical limiting factors to integrated circuits performance. The RC delay is proportional directly to the resistivity of the metal and the dielectric constant of the dielectric used in the interconnect system. In order to minimize a signal propagation delay, it is inevitable to use low dielectric constant materials as inter-layer and intra-layer dielectrics (ILD). While many low-k (k<3.0) materials have been used as ILDs, silicon nitride (SiN) with a high dielectric constant (k>7.0) is still the primary candidate for ESL (etch stop layer) required in copper damascene structures. Thus, it is desirable to replace silicon nitride by new materials with lower dielectric constants to further reduce the effective dielectric constant of the Cu interconnect system. In recent years, an increasing interest has been focused on study of high stress and thermally stable low-k silicon carbide based films deposited by PECVD using organosilicon gases. The use of silicon carbide films as copper diffusion barrier layers has been published in U.S. Pat. No. 5,800,878. The dielectric constant of this film is about 5, and in addition, it is used as copper diffusion barrier layers for 130 nm/90 nm-nodes Large Scale Integration (LSI) technologies where the dielectric constant of the interlayer dielectric film is 3.

When pure or fluorine-doped SiO2 and SiN are deposited in a CVD reactor, sediment on inner surfaces of the CVD reactor can be removed by remote plasma cleaning. To reduce green house effect, NF3 gas is generally applied with remote plasma technology. In that case, Argon gas is added as a feedstock to stabilize plasma discharge in a remote plasma chamber isolated from the CVD reactor. This technology is disclosed in U.S. Pat. No. 6,187,691, and U.S. Patent Publication No. 2002/0011210A. The following references also disclose chamber cleaning technologies. U.S. Pat. No. 6,374,831, U.S. Pat. No. 6,387,207, U.S. Pat. No. 6,329,297, U.S. Pat. No. 6,271,148, U.S. Pat. No. 6,347,636, U.S. Pat. No. 6,187,691, U.S. Pat. No. 6,352,945, and U.S. Pat. No. 6,383,955. The disclosure of the foregoing references is herein incorporated by reference in their entirety, especially with respect to configurations of a reactor and a remote plasma reactor, and general cleaning conditions.

The above conventional cleaning methods have problems explained below.

As low-k films used for ILDs, carbon-containing silicon oxide films comprising Si, 0, C, and H are used. Silicon carbide films used as ESL include SiCNH, SiCH, SiCOH, etc. These carbon-containing films have slow cleaning rates when used with conventional cleaning methods using NF3, lowering throughput capacity of apparatus. On the other hands, in NF3 remote plasma cleaning, silicon nitride films and fluorine active species react each other at faster rates, and a cleaning rate of 2 microns/min. can be achieved for cleaning a reactor used for forming silicon nitride films (U.S. Patent Publication No. 2002/0011210A1, U.S. Pat. No. 5,788,778, and U.S. Pat. No. 6,374,831).

However, in the case of silicon oxide films, cleaning rates are approximately 1 to 1.5 microns/min.; cleaning rates of silicon carbide films are 0.08 to 0.2 microns/min. Such slow cleaning rates become the primary cause for lowering throughput capacity of apparatus.

In addition to remote plasma cleaning, as described in U.S. Patent Publication No. 2003/0192568A1 and U.S. Patent Publication No. 2003/0029475A1, there is a method which applies radio-frequency power to electrodes set up inside the CVD chamber. Using this method applying radio-frequency power to discharge electrodes, which are set up inside the CVD chamber and used for forming a film, extinguishes merits of the remote plasma cleaning which is used for minimizing damage to parts inside the CVD chamber. Consequently, although cleaning rates are improved, electrode deterioration is caused by application of the radio-frequency power to the electrodes inside the CVD chamber.

### SUMMARY OF THE INVENTION

Objectives of the present invention are to provide an apparatus and a method enabling to clean products adhering to an inner surface of the CVD reactor at high rates; particularly, a method of speeding up rates of cleaning the inner surface of the CVD reactor used for forming carbon-containing films including silicon carbide films and an apparatus used for the same. Further, another objective is to provide a CVD apparatus having high throughput attributed to higher cleaning rates.

In one aspect, the present invention provides a thin-film deposition system comprising: (i) a plasma CVD reactor; (ii) a remote plasma chamber arranged outside the plasma CVD reactor, for providing active species to an interior of the plasma CVD; and (iii) an electromagnetic wave generator arranged outside the plasma CVD reactor and the remote plasma chamber, for emitting electromagnetic waves to the interior of the reactor. In this embodiment, unwanted reaction products adhering to an inner surface of the reactor absorb electromagnetic waves, are heated, changed into a gas by reactions with cleaning active species, and evacuated from the reactor. In the above, there is no limitation imposed on the specific configurations of the plasma CVD reactor or the remote plasma chamber. To be more efficient cleaning, the remote plasma chamber generates an inductively-coupled plasma to excite the cleaning gas. Additionally, more than one electromagnetic waves generator can be installed.

The devices disclosed in the references which are incorporated herein by reference can be used in the present invention in some embodiments.

Although any electromagnetic waves can be used as long as the waves facilitate reactions between the cleaning active species and unwanted reaction products accumulated on an inner surface of the reactor. Infrared rays or microwaves can effectively be used for the above purpose. In an embodiment, the electromagnetic waves are microwaves which have a wave length of 3×10⁻⁴ to 3×10⁻¹ m or a frequency of 1 to 1000 GHz. Preferably, microwaves having ultrahigh frequencies (UHF, 0.3-3 GHz; preferably 2-3 GHz) may be used.

The power of electromagnetic wave emission can very, depending on the frequency of the waves, the type of a film formed on a substrate (i.e., the type of a unwanted deposition on an inner surface), the type of cleaning gas, the temperature of cleaning process, the pressure of cleaning process, the volume of the reactor, the location of an inlet of the electromagnetic waves, etc. The electromagnetic waves have power sufficient to facilitate reactions between unwanted products adhering to an inner surface of the reactor and the cleaning active species derived from the cleaning gas. In an embodiment, the power is in the range of 100-5,000 W (including 200, 300, 400, 500, 1,000, 1,500, 2,000, 3,000, 4,000 W, and any ranges between any two numbers of the foregoing).

The reactor and the electromagnetic wave generator can be connected by any means as long as electromagnetic waves are emitted into the reactor. In an embodiment, the reactor and the electromagnetic wave generator are connected by a waveguide. In the above, the reactor may comprise a sapphire window where the waveguide is connected. In another embodiment, the reactor and the electromagnetic wave generator are connected by a co-axial cable.

The electromagnetic wave generator may be connected to a side wall of the reactor in a direction perpendicular to an axis of radio-frequency electrodes arranged in the reactor, although the invention is not limited to the above configuration. The reactor may comprise an upper electrode and a lower electrode, between which a substrate is placed. Thus, the side wall of the reactor is a suitable place for connecting the electromagnetic wave generator. Further, unwanted reaction products are accumulated more on a showerhead which functions as an upper electrode than on other inner walls, because the temperature of the showerhead is lower than the other walls during deposition of a thin film on a substrate. Thus, it is preferably to locate an inlet of electromagnetic waves in such a way that the showerhead is more irradiated with electromagnetic waves than are the other walls.

Because the electromagnetic waves are used for cleaning the reactor, not for depositing a thin film on a substrate, in an embodiment, the system further comprises a controller which activates the electromagnetic wave generator only for reactor cleaning.

In another aspect, the present invention provides a method for cleaning a plasma CVD reactor, comprising: during a cleaning cycle, (i) providing cleaning active species derived from a cleaning gas in the plasma CVD reactor, and (ii) emitting electromagnetic waves, independently of step (i), from an outside of the plasma CVD reactor into an interior of the plasma CVD reactor.

In the above, step (i) and step (ii) can be conducted simultaneously, or in another embodiment, step (ii) may be initiated prior to step (i). However, step (i) can be initiated prior to step (ii). Preferably, when step (ii) is activated, cleaning active species are present in the interior of the reactor. Both steps (i) and (ii) may continue until the end of a cleaning cycle. However, step (ii) can be conducted intermittently or in pulses during a cleaning process.

Preferably, the cleaning gas is excited in a remote plasma chamber and introduced into the interior of the reactor, so that the excitation process of the cleaning gas will not damage the inner parts of the reactor during a cleaning cycle.

The cleaning gas may comprise a fluorine-containing gas, and the active species may be fluorine active species. Fluorine active species are effective to react with silicon components. Further, if unwanted reaction products contain oxygen, such as silicon dioxide and siloxan polymer, and if the cleaning gas does not contain carbon, the cleaning gas may be a gas comprising fluorine (F2), fluorine trinitride (NF3), or a mixture of the foregoing without oxygen-containing gas or with a slight amount of oxygen-containing gas.

On the other hand, if unwanted reaction products contain no or very little oxygen, such as silicon nitride and silicon carbide, and if the cleaning gas contains carbon, such as a gas comprising a fluorocarbon compound (e.g., CF4, C2F6, C3F8, COF2), an oxygen-containing gas may be added to the cleaning gas (in this case, the cleaning gas includes the oxygen-containing gas). Oxygen is effective to remove carbon components.

In the present invention, the cleaning rate is increased by applying electromagnetic waves to an inner surface of the reactor, and even if unwanted reaction products are carbon-containing films such as silicon carbide (SiCNH, SiCH, SiCOH, etc.), cleaning can be accomplished efficiently.

General conditions for cleaning are as follows:

A cleaning gas comprising: (1) a fluorine-containing gas (100-2000 sccm, including 200, 300, 500, 750, 1000, 1500 sccm, and any ranges between any two numbers of the foregoing); (2) an oxygen-containing gas (100-2000 sccm, including 200, 300, 500, 750, 1000, 1500 sccm, and any ranges between any two numbers of the foregoing); (3) an inert gas (0-2000 sccm, including 200, 400, 600, 1000, 1500 sccm, and any ranges between any two numbers of the foregoing). If no carbon components are present in the unwanted products or the cleaning gas, no oxygen is necessary.

2) Pressure of the reactor: 100-2000 Pa, including 200, 300, 500, 1000, 1500 Pa, and any ranges between any two numbers of the foregoing.

3) Temperature of the reactor (the temperature of a susceptor): 100-700° C., including 200, 300, 400, 500, 600° C., and any ranges between any two numbers of the foregoing. By applying electromagnetic waves to unwanted reaction products, the products' temperature increases by approximately 10-500° C. (20, 30, 50, 100, 200, 300, 400° C., and any ranges between any two numbers of the foregoing), as compared with the case where no electromagnetic waves are applied. However, the inner wall of the reactor itself is not significantly heated by the exposure of electromagnetic waves and the increasing temperature of the unwanted reaction products, because it has higher heat capacity and is not made of polar materials.

4) The cleaning rate: 300-3000 nm/min, including 400, 500, 750, 1000, 1500, 2000 nm/min, and any ranges between any two numbers of the foregoing. The cleaning rate can be regulated as a function of power of electromagnetic waves. The cleaning period can be determined based on the thickness of unwanted products.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention.

FIG. 1 is a schematic diagram illustrating a plasma CVD apparatus provided with a device discharging electromagnetic waves for enhancing cleaning efficiency.

FIG. 2 is a schematic diagram illustrating another plasma CVD apparatus provided with another device discharging electromagnetic waves for enhancing cleaning efficiency.

### DETAILED DESCRIPTION OF THE PREFERRED EMBODIMENT

The invention will be explained further with reference to specific embodiments, but the invention should not be limited thereto.

As explained above, in an embodiment, a thin-film deposition apparatus forming a thin film onto a substrate, comprises a reactor for storing the substrate and for forming a thin film onto the substrate, a remote plasma chamber for activating a cleaning gas used for removing reaction product adhering to an inner surface of the reactor during thin-film deposition onto the substrate, and an electromagnetic wave feeding unit connected to the reactor for irradiating electromagnetic waves to interior of the reactor.

After a carbon-containing silicon oxide film or a silicon carbide film is deposited onto the substrate inside the reactor, the substrate is brought out from the reactor.

A cleaning gas containing fluorine is introduced into the remote plasma chamber at a given flow rate; plasma discharge is formed inside the remote plasma chamber; the cleaning gas is activated; activated cleaning gas (i.e., “cleaning active species”) is introduced into the reactor. Simultaneously, electromagnetic waves are emitted to the interior of the reactor from the electromagnetic feeding unit.

The reaction products adhering to interior of the reactor absorb electromagnetic waves, are heated, changed into a gas by the cleaning active species, and evacuated from the reactor.

If a film deposited onto the substrate is a silicon carbide film (having Si, C, H or Si, C, N, H or Si, C, 0, H as it components), a mixed gas of NF3, oxygen and inert gas is used as a cleaning gas. COF2, C2F6, C3F8, C4F8, CF4 and oxygen-containing gas (e.g. oxygen, CO2, O3, NO2, N2O, CO, H2O, NOF, H2O2) can also be used as a cleaning gas. Additionally, F2, and F2 and inert gas or oxygen, or nitrogen, or a mixed gas with NF3, a mixed gas of F2 and oxygen-containing gas can also be used as a cleaning gas.

As electromagnetic waves emitted to the interior of the reactor, using microwaves (2.45 GHz) is effective. Microwaves are introduced toward interior of the reactor.

If a thin film deposited onto the substrate is a film containing a high percentage of oxygen, an amount of oxygen-containing gas in a cleaning gas can be reduced; if a film does not contain carbon such as a silicon nitride film or a silicon oxide film, an amount of oxygen-containing gas can be reduced to zero if F2 or NF3 is used as a cleaning gas. If a cleaning gas itself contains carbon such as CF4, C2F6 or COF2, an oxygen-containing gas is used by mixing it with a cleaning gas to prevent carbon from remaining inside the reactor, or a carbon film or carbon particles from remaining inside the reactor or the remote plasma chamber. Particularly, an oxygen-containing gas is effective to prevent carbon components from remaining inside the reactor or the remote plasma chamber. When a carbon-containing thin film is deposited onto the substrate, an oxygen-containing gas is introduced into the remote plasma chamber with a fluorine-containing gas, which is a cleaning gas.

### EXAMPLES

Embodiments of the present invention are described below.

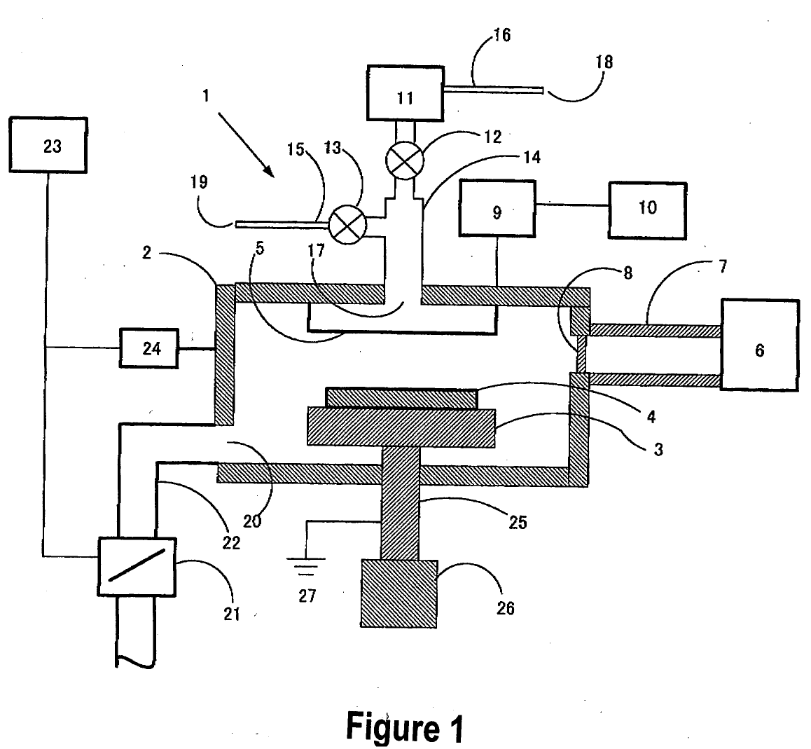

FIG. 1 indicates an embodiment of a thin-film deposition apparatus according to the present invention. A semiconductor substrate 4, onto which a carbon-containing silicon oxide film or a silicon carbide film is deposited, is placed on a susceptor heater 3 set up inside a reactor 2. Inside the reactor 2, a showerhead 5 used for feeding a reaction gas into a reactor 5 is set up in a position opposing to the susceptor heater 3. The susceptor heater 3, in which a resistance-heating-type sheath heater (not shown) and a temperature sensor (not shown) are embedded, is kept at constant high temperature by an external temperature controller (not shown). The heated susceptor heater 3 heats the semiconductor substrate 4 to a given appropriate temperature appropriate for film deposition. In the reactor 2, an exhaust port 20 for evacuating the interior of the reactor is provided and is connected to a vacuum pump (not shown) through exhaust piping 22 and a conductance-regulating valve 21. Instructed by an automatic pressure controller 23 based on a pressure value inside the reactor measured by a pressure sensor 24 connected to the reactor 2, the conductance-regulating valve 21 regulates a pressure inside the reactor 2 at a given value.

With its flow rate controlled at a given value by a mass flow controller (not shown), a reaction gas used for depositing a film onto the semiconductor substrate 4 is introduced into the reactor 2 from a port 19 via piping 15, a valve 13, inlet piping 14 and an opening 17. The reaction gas flowing in from the opening 17 is fed into the showerhead 5 and to the upper surface of the semiconductor substrate 4 through thousands of fine pores (not shown) provided in a surface of the showerhead 5 facing the semiconductor substrate 4. To deposit a film onto the semiconductor substrate 4 by decomposing the reaction gas, a radio-frequency power generator 10 is connected to the showerhead 5 via a radio-frequency power matching circuit 10. Plasma discharge is formed between the showerhead 5 and the susceptor heater 3 supporting the semiconductor substrate 4.

With its flow rate regulated at a given value by a mass flow controller (not shown), a cleaning gas used for cleaning interior of the reactor 2 after thin-film deposition onto the semiconductor substrate 4 is introduced to a remote plasma chamber 11 from a port 18 through piping 16. The cleaning gas is excited and activated by radio-frequency discharge in the remote plasma chamber. Activated cleaning gas is introduced into the reactor 2 from the opening 17 via a valve 12 and inlet piping 14. Upon introducing the cleaning gas activated in the remote plasma chamber 11 into the reactor 2, microwaves are introduced into the reactor 2 from a microwave generator 6 through a waveguide 7 and a sapphire window 8. Reaction products adhering to interior surfaces of the reactor during film deposition onto the semiconductor substrate 4 are heated by microwaves; a reaction rate of the product with the activated cleaning gas increases.

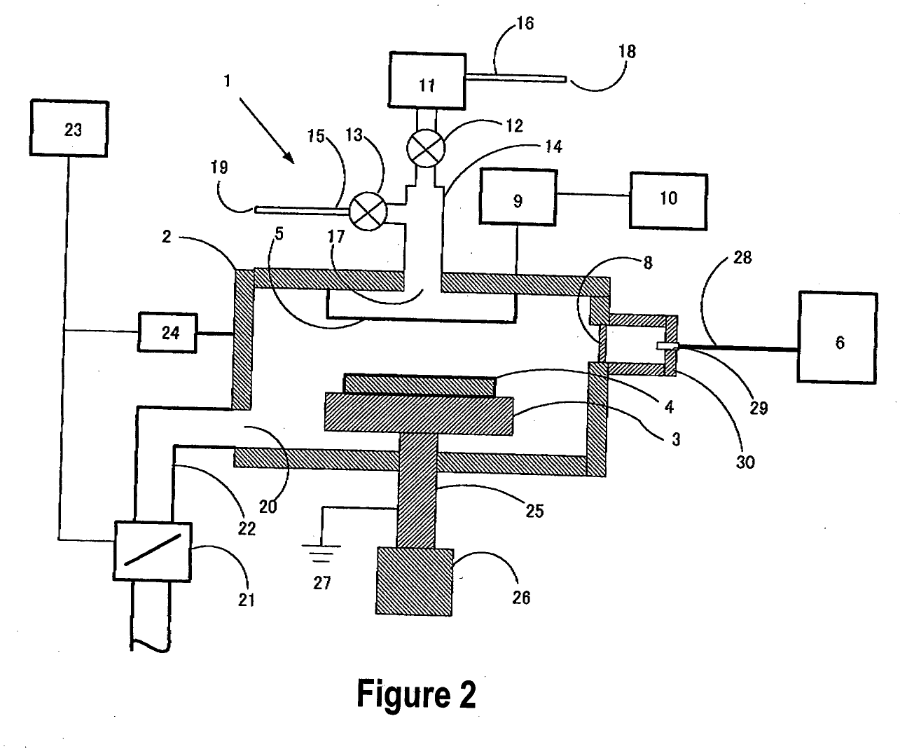

In FIG. 2, another embodiment according to the present invention is shown. In this embodiment, microwaves which are emitted from a microwave generator 6 having magnetron is emitted into a waveguide 30 from a converter 29 via a co-axial cable 28. Microwaves are fed into the reactor from the window 8 installed in the reactor 2.

Cleaning the interior of the reactor after film deposition is described below with reference to FIG. 1.

When a silicon carbide film was deposited onto the silicon substrate (the semiconductor substrate 4), a mixed gas of tetramethylsilane, Si(CH3)4, with its flow rate controlled at 150 to 500 sccm, preferably at 200 to 300 sccm, by a mass flow controller (not shown), helium with its flow rate controlled at 1 to 5 slm, preferably at 2 to 3 slm, by a separately provided flow controller (not shown), and ammonia with its flow rate controlled at 100 to 500 sccm, preferably at 200 to 300 sccm, was introduced to an upper area of the semiconductor substrate 4 from the showerhead 5 set up inside the reactor 2 from the inlet piping 14 and the opening 17 by opening the valve 13.

At this time, the semiconductor substrate 4 was heated at approximately 340 to 350° C. by the susceptor heater heated at 355° C., and a distance between the semiconductor substrate 4 and the showerhead 5 was kept at 15 to 30 mm, preferably at 17 to 22 mm. In this state, with a pressure inside the reactor 2 maintained at 665 Pa, radio-frequency power (of 27.12 MHz at 600 W and 400 kHz at 75 W mixed) was applied to the showerhead 5; plasma discharge was formed between the showerhead 5 including the semiconductor substrate 4 and the susceptor heater 3.

Consequently, a silicon carbide film comprising SiCNH was successfully deposited on the semiconductor substrate 4 at a rate of 100 nm/min. When the silicon carbide film was deposited onto the semiconductor substrate 4, the valve 12 was closed. After film deposition onto the semiconductor substrate 4 was completed, the semiconductor substrate was carried out from the reactor 2. Reaction products adhering to interior of the reactor 2 by film deposition were cleaned according to the following procedure:

NF3 with its flow rate controlled at 200 to 500 sccm, oxygen with its flow rate controlled at 200 to 500 sccm and Ar with its flow rate controlled at 400 to 1000 sccm were introduced to the remote plasma chamber from the port 18. In the remote plasma chamber, fluorine active species were generated by a toroidal discharge plasma generated by 400 kHz radio-frequency power. By opening the valve 12, the fluorine active species were led to the inlet piping 14 and were introduced into the reactor 2 from the opening 17 through the showerhead 5. Upon or prior to introduction of these fluorine active species into the reactor 2, microwaves at 500 to 2000 W were emitted to the interior of the reactor 2 from the microwave generator 6 through the waveguide 7 and the sapphire window 8.

When 280 sccm of NF3, 330 sccm of O2 and 800 sccm of Ar were introduced and a pressure inside the reactor reached 400 Pa, a toroidal plasma was formed in the remote plasma chamber by irradiation of 400 kHz radio frequency at 2.9 kW. When microwaves were emitted into the reactor 2 from the microwave generator 6 upon introduction of fluorine-oxygen active species into the reactor 2 by generating the species, the reaction product adhering during deposition of the above-mentioned silicon carbide film of 200 nm was successfully cleaned in 24 seconds. In terms of a film thickness deposited, a cleaning rate obtained was 500 nm/min.

For comparison, cleaning the interior of the reactor was conducted by stopping feeding microwaves from the microwave generator 6 and only by introducing fluorine-oxygen active species. It took 60 seconds to clean the interior of the reactor after a silicon carbide film of 200 nm was deposited. In terms of a film thickness deposited, a cleaning rate was 200 nm/min. Adding microwave irradiation increased a cleaning rate after a silicon carbide film was deposited to 200 to 500 nm/min.

Furthermore, when argon was excluded from the gases introduced into the remote plasma chamber 11, its cleaning rate increased to 1000 nm/min. When an inductively-coupled plasma was formed in the remote plasma chamber with microwaves at the reactor controlled at 400 Pa, and fluorine-oxygen active species were introduced into the reactor 2, its cleaning rate increased to 2000 nm/min. To form an inductively-coupled plasma in the remote plasma chamber, a coil was wound around a pipe comprising a dielectric. As a derivative, ceramic, preferably alumina ceramic or sapphire, can be used. Radio-frequency power of 2 to 27.12 MHz at 2 to 3 kW is applied to the coil.

Cleaning the interior of the reactor 2 when, a carbon-containing silicon oxide film (SiOCH) was deposited is described below.

To deposit a carbon-containing silicon oxide film onto the semiconductor substrate 4, 140 sccm of DMDMOS (Dimethyl-dimethoxysilane; Si(CH3)2(OCH3)2), and 50 sccm of He were fed into the reactor 2. The semiconductor substrate 4 was heated approximately at 380° C. and was placed on the susceptor heater at a 20 to 30 mm distance from the showerhead 5. With a pressure inside the reactor 2 controlled at 400 to 700 Pa and by applying 27.12 MHz radio-frequency power at 1.5 kW to the showerhead 5, a plasma discharge area was formed between the showerhead 5 including the semiconductor substrate 4 and the susceptor heater 3.

By this plasma discharge, a carbon-containing silicon oxide film was formed onto the semiconductor substrate 4 at a rate of 500 to 700 nm/min. After film deposition was finished, cleaning the interior of the reactor 2 was conducted as follows:

900 sccm of NF3, 100 sccm of O2 and 5.5 slm of Ar were fed into the remote plasma chamber 11, activated, and introduced into the reactor 2 with its interior pressure controlled at 790 Pa; cleaning the interior of the reactor 2 was conducted at a rate of 1000 nm/min. When microwaves at 750 W emitted interior of the reactor 2 during cleaning conducted under the same conditions, a cleaning rate of 1500 nm/min. was obtained. Further, when microwaves at 1000 W were used, a cleaning rate of 1750 nm/min. was obtained.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A thin-film deposition system comprising:
a plasma CVD reactor;
a remote plasma chamber arranged outside the plasma CVD reactor, for providing active species to an interior of the plasma CVD; and
an electromagnetic wave generator arranged outside the plasma CVD reactor and the remote plasma chamber, for emitting electromagnetic waves to the interior of the reactor.

2. The system according to claim 1, wherein the electromagnetic waves are microwaves.

3. The system according to claim 1, wherein the reactor and the electromagnetic wave generator are connected by a waveguide.

4. The system according to claim 3, wherein the reactor comprises a sapphire window where the waveguide is connected.

5. The system according to claim 1, wherein the reactor and the electromagnetic wave generator are connected by a co-axial cable.

6. The system according to claim 1, further comprising a controller which activates the electromagnetic wave generator only for reactor cleaning.

7. The system according to claim 1, wherein the electromagnetic wave generator is connected to a side wall of the reactor in a direction perpendicular to an axis of radio-frequency electrodes arranged in the reactor.

8. The system according to claim 1, wherein the remote plasma generates an inductively-coupled plasma.

9. A method for cleaning a plasma CVD reactor, comprising:
during a cleaning cycle, (i) providing cleaning active species derived from a cleaning gas in the plasma CVD reactor, and (ii) emitting electromagnetic waves, independently of step (i), from an outside of the plasma CVD reactor into an interior of the plasma CVD reactor.

10. The method according to claim 9, wherein the cleaning gas is excited in a remote plasma chamber and introduced into the interior of the reactor.

11. The method according to claim 9, wherein the electromagnetic waves are microwaves.

12. The method according to claim 9, wherein the electromagnetic waves have power sufficient to facilitate reactions between unwanted products adhering to an inner surface of the reactor and the cleaning active species derived from the cleaning gas.

13. The method according to claim 9, wherein the cleaning gas comprises a fluorine-containing gas.

14. The method according to claim 9, wherein the cleaning gas comprises fluorine, fluorine trinitride, or a mixture of the foregoing.

15. The method according to claim 9, wherein the cleaning gas comprises a fluorocarbon compound and an oxygen-containing gas.

16. The method according to claim 9, wherein the cleaning gas comprises COF2.

17. The method according to claim 9, wherein step (i) and step (ii) are simultaneously conducted.

18. The method according to claim 9, wherein step (ii) is initiated prior to step (i).

19. The method according to claim 9, wherein step (i) is initiated without step (ii), and then step (i) and step (ii) are conducted in parallel.

20. The method according to claim 9, wherein step (ii) is initiated without step (i), and then step (i) and step (ii) are conducted in parallel.

21. The method according to claim 9, wherein the cleaning active species are generated by an inductively-coupled plasma produced in a remote plasma chamber.

22. A method for manufacturing multiple substrates having films deposited thereon, comprising the steps of:
treating multiple substrates using a single-substrate processing plasma CVD reactor; and
initiating a cleaning cycle by (i) providing cleaning active species derived from a cleaning gas in the plasma CVD reactor, and (ii) emitting electromagnetic waves from an outside of the plasma CVD reactor into an interior of the plasma CVD reactor.
